(19) United States
(12) Patent Application Publication
(10) Pub. No.: US 2007/0172083 A1
(43) Pub. Date: Jul. 26, 2007

(54) METHOD AND APPARATUS FOR CONTROLLING A GAIN OF A VOICE SIGNAL

(76) Inventors: Cheng-Te Tseng, Taipei City (TW); Hung-Yi Chen, Hsin-Chu City (TW); Yen-Ju Huang, Taipei Hsien (TW); Wei-Nan William Tseng, Taipei City (TW)

Correspondence Address: NORTH AMERICA INTELLECTUAL PROPERTY CORPORATION, P.O. BOX 506, MERRIFIELD, VA, 22116, US

(21) Appl. No.: 11/307,152

(22) Filed: Jan. 25, 2006

(51) Int. Cl. H03G 3/00

(52) U.S. Cl. 381/104

(57) ABSTRACT

A method for controlling a gain of a voice signal comprises detecting a size of an image of an object; determining a signal gain according to the size of the image of the object; and applying the signal gain to a voice signal. The method is capable of adaptively controlling the gain of the voice signal according to a distance between a user and an audio system.

### BACKGROUND OF THE INVENTION

1. Field of the Invention

The present invention relates to a method for controlling a gain of a voice signal, and more particularly, to a method for controlling a gain of a voice signal according to a distance between a user and an audio system.

2. Description of the Prior Art

As related technology keeps improving, various types of electronic devices are capable of executing complex audio/video functions. For example, a mobile phone can play MP3 music, record voice, or even handle a video conference. When in a video conference, a user usually keeps a distance away from a microphone or a speaker of the mobile phone (or related devices), and sometimes the user may move around. However, an audio system of the mobile phone controls an input gain of the microphone and an output gain of the speaker as constants until the user changes them manually. When the user is far away from the mobile phone, the volume of the speaker will be too small to hear if the output gain of the speaker is not enough. Similarly, the microphone will not be able to receive the user's voice if the input gain of the microphone is not enough.

In conclusion, audio system of the prior art cannot adaptively change the input gain of the microphone or the output gain of the speaker according to the distance between a user and the audio system.

### SUMMARY OF THE INVENTION

It is therefore an objective of the claimed invention to provide a method for controlling a gain of a voice signal in order to solve the problems of the prior art.

The present invention provides a method for controlling a gain of a voice signal that comprises detecting a size of an image of an object; determining a signal gain according to the size of the image of the object; and applying the signal gain to a voice signal.

The present invention further provides an audio system comprising an image detector for detecting a size of an image of an object; a gain estimator coupled to the image detector for determining a signal gain according to a focus value of the image detector and the size of the image of the object; and a gain controller coupled to the gain estimator for applying the signal gain a voice signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram showing an audio system of the present invention detecting a distance between a user and the audio system.

FIG. 2 is a functional block diagram of the audio system in FIG. 1.

FIG. 3 is a diagram showing the gain estimator of the present invention estimating a gain of a voice signal according to a predetermined gain distribution chart.

FIG. 4 is a flowchart showing a method of the present invention.

### DETAILED DESCRIPTION

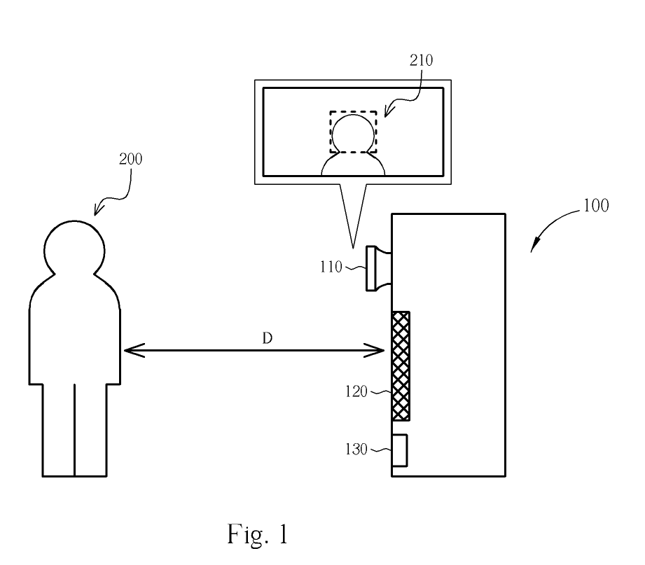

Please refer to FIG. 1, which shows an audio system 100 of the present invention detecting a distance between a user 200 and the audio system 100. Because an energy level of a voice signal is inversely proportional to the square of a transmitting distance, the audio system 100 of the present invention controls a gain of a voice signal according to a distance between a user 200 and the audio system 100. As shown in FIG. 1, an image detector 110 of the audio system 100 is utilized for detecting a size of a captured image of an object, which is, for example a size of a captured image of the user's face 210. Therefore, the distance between the user 200 and the audio system 100 can be further determined according to the below equation:
D=K×F/Y (1)

D is the distance between the user 200 and the audio system 100, F if the focus value of the image detector 110, Y is the size of the captured image of the user's face 210, and K is a known constant. If the image detector 110 has a variable focus lens module, the audio system 100 determines the distance D according to both the focus value F of the image detector 110 and the size Y of the captured image of the user's face 210. On the other hand, if the image detector 110 has a fixed focus lens module, the audio system 100 determines the distance D only according to the size Y of the captured image of the user's face 210.

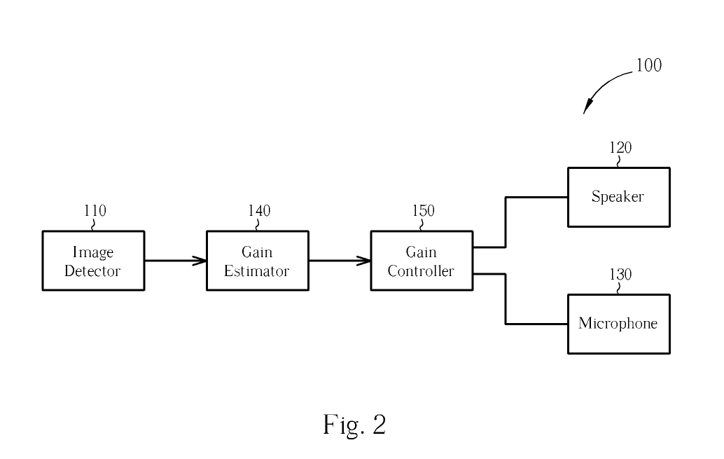

Please refer to FIG. 2, and refer to FIG. 1 as well. FIG. 2 is a functional block diagram of the audio system 100 in FIG. 1 . After the distance D is determined, the audio system 100 of the present invention can adaptively control a gain of a voice signal according to the value of the distance D. For example, at the beginning the user can set a proper output gain G₁ of a voice signal through the speaker 120 while the user 200 stands away from the audio system 100 at a distance D₁. If the user 200 moves to another position, the image detector 110 senses a change of the size Y of the captured image of the user's face 210. Then, the gain estimator 140 determines a new distance D₂ according to the focus value F of the image detector 110 and a new size Y of the captured image of the user's face 210 (assuming the image detector 110 has a variable focus lens module). After obtaining the new distance D₂, the gain estimator 140 generates a new output gain G₂ of the voice signal through the speaker 120 according to the original output gain G₁, distance D₁, and distance D₂. The equation to obtain the new output gain G₂ is shown below:
G₂=(D₁²/D₂²)×G₁ (2)

Thereafter, the gain controller 150 applies the new output gain G₂ to the voice signal through the speaker 120, such that the user 200 can hear clearly even while moving around. Similarly, an input gain of a voice signal through a microphone 130 can be adaptively controlled according the above method as well.

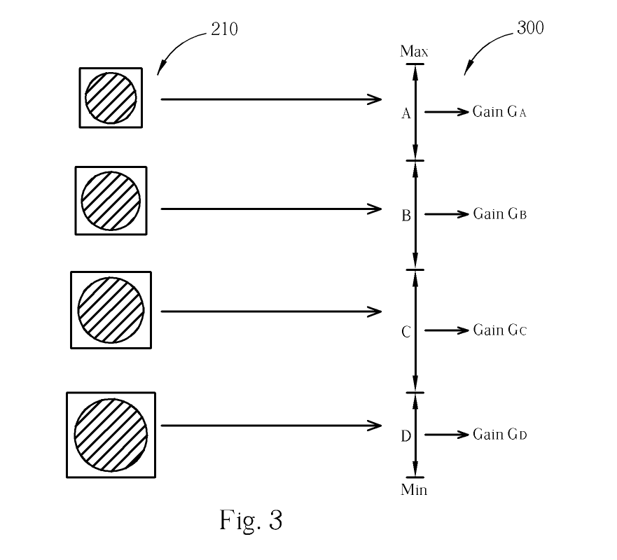

In addition, the gain estimator 140 of the present invention can also generate a new gain of a voice signal directly according to the size Y of the captured image of the user's face 210. Please refer to FIG. 3, which shows the gain estimator 140 of the present invention estimating a gain of a voice signal according to a predetermined gain distribution chart 300. As shown in FIG. 3, after receiving information of the size Y of the captured image of the user's face 210 from the image detector 110, the gain estimator 140 can generate a new gain of a voice signal by directly mapping the size Y of the captured image of the user's face 210 to a predetermined gain distribution chart 300. For example, if the size Y of the captured image of the user's face 210 falls in a range A, the size Y will be mapped to a gain G_{A}. Likewise, if the size Y of the captured image of the user's face 210 falls in a range C, the size Y will be mapped to a gain G_{C}, and so on for ranges B and D and respective gains G_{B} and G_{D}.

Therefore, the audio system 100 can adaptively change the input gain of the microphone 130 or the output gain of the speaker 120 according to the distance between the user 200 and the audio system 100. For example, when the user 200 is moving away from the audio system 100, the audio system 100 will increasing the volume (output gain) of the speaker 120 and the sensitivity (input gain) of the microphone 130 correspondingly. On the other hand, when the user 200 is moving toward the audio system 100, the audio system 100 will decreasing the volume of the speaker 120 and the sensitivity of the microphone 130 correspondingly. Such that the audio system 100 of the present invention is able to provide proper outputting and inputting performance even when the user 200 is moving around.

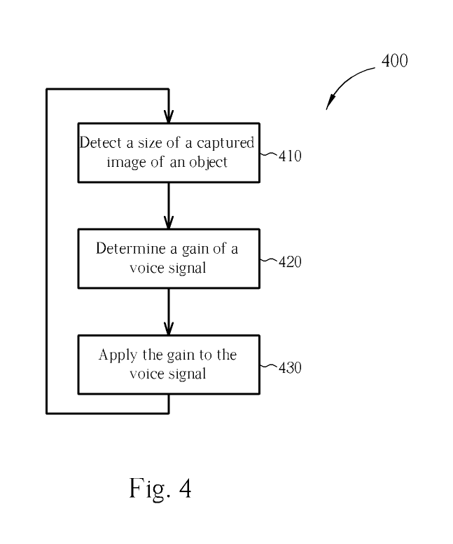

To more clearly illustrate the method for controlling a gain of a voice signal, FIG. 4 provides a flowchart 400 of a method of the present invention. Please refer to FIG. 4, and refer to FIG. 1 and FIG. 2 as well. The flowchart 400 of FIG. 4 comprises the following steps:

Step 410: Detect a size of a captured image of an object;

Step 420: Determine a gain of a voice signal according to the size of the captured image of the object;

Step 430: Apply the gain to the voice signal, and return to step 410.

Basically, to achieve the same result, the steps of the flowchart 400 need not be in the exact order shown and need not be contiguous, that is, other steps can be intermediate.

Summarizing the above, the present invention utilizes an image detector 110 to sense a size of a captured image of an object in order to estimate a distance between a user 200 and the audio system 100, and then controls a gain of a voice signal according to the distance between the user 200 and the audio system 100.

In contrast to the prior art, the present invention can adaptively change the input gain of the microphone 130 or the output gain of the speaker 120 according to the distance between the user 200 and the audio system 100, such that the audio system 100 of the present invention is able to provide proper outputting and inputting performance even when the user 200 is moving around.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for controlling a gain of a voice signal, the method comprising the following steps:
detecting a size of an image of an object;
determining a signal gain according to the size of the image of the object; and
applying the signal gain to a voice signal.

2. The method of claim 1 wherein determining a signal gain according to the size of the image of the object comprises determining a signal gain of a voice signal according to a focus value and the size of the image of the object.

3. The method of claim 1 further comprising outputting a voice signal through a speaker.

4. The method of claim 3 wherein applying the signal gain to a voice signal comprises determining a volume of the speaker.

5. The method of claim 1 further comprising receiving a voice signal through a microphone.

6. The method of claim 5 wherein applying the signal gain to a voice signal comprises determining a gain of a microphone gain controller.

7. The method of claim 6 wherein detecting a size of an image of an object further comprising capturing the image of the object according to a source of the voice signal.

8. The method of claim 1 wherein the size of the image of the object is a size of a captured image of a human face.

9. An audio system comprising:
an image detector for detecting a size of an image of an object;
a gain estimator coupled to the image detector for determining a signal gain according to the size of the image of the object; and
a gain controller coupled to the gain estimator for applying the signal gain to a voice signal.

10. The audio system of claim 6 wherein the size of the image of the object is a size of a captured image of a human face.

11. The audio system of claim 9 wherein the signal gain is a gain of outputting the voice signal through a speaker.

12. The audio system of claim 9 wherein the signal gain is a gain of receiving the voice signal through a microphone.

13. An audio system comprising:
an image detector for detecting a size of an image of an object;
a gain estimator coupled to the image detector for determining a signal gain according to a focus value of the image detector and the size of the image of the object; and
a gain controller coupled to the gain estimator for applying the signal gain to a voice signal.

14. The audio system of claim 13 wherein the size of the image of the object is a size of a captured image of a human face.

15. The audio system of claim 13 wherein the signal gain is a gain of outputting the voice signal through a speaker.

16. The audio system of claim 13 wherein the signal gain is a gain of receiving the voice signal through a microphone.
